(19) United States
(12) Patent Application Publication
(10) Pub. No.: US 2026/0190787 A1
(43) Pub. Date: Jul. 2, 2026

(54) Light Emitting Display Device

(71) Applicant: LG Display Co., Ltd., Seoul (KR)

(72) Inventors: Ji Sub Park, Paju-si (KR); Kyung Mi Kim, Paju-si (KR); Byeong Gon Kim, Paju-si (KR)

(21) Appl. No.: 19/429,589

(22) Filed: Dec. 22, 2025

(30) Foreign Application Priority Data
Dec. 31, 2024 (KR) 10-2024-0202822

(51) Int. Cl. H10K 59/80; H10K 59/40

(52) U.S. Cl. CPC H10K 59/873; H10K 59/40

(57) ABSTRACT

Disclosed is a light emitting display device including a substrate including an active area having a hole and a non-active area, a plurality of subpixels in the active area to be spaced apart from the hole by more than a first distance, a transistor provided in each of the plurality of subpixels, a light emitting element at each of the plurality of subpixels, the light emitting element including a first electrode connected to the transistor, a second electrode opposite the first electrode, and an intermediate layer between the first and second electrodes, an intermediate layer disconnection structure provided within the first distance to surround the hole, the intermediate layer disconnection structure having an undercut shaped section, an encapsulation layer on the light emitting element, the encapsulation layer to cover the intermediate layer disconnection structure, and a touch sensor on the encapsulation layer.

### CROSS REFERENCE TO RELATED APPLICATION

This application claims priority under 35 U.S.C. § 119(a) to the Republic of Korea Patent Application No. 10-2024-0202822, filed on Dec. 31, 2024, the entire contents of which are hereby expressly incorporated by reference into the present application.

### TECHNICAL FIELD

The present disclosure relates to a light emitting display device that improves the reliability of a structure having a hole in an active area.

### BACKGROUND

Display devices for displaying images on TVs, monitors, smartphones, tablet computers, and laptop computers, etc. are used in various ways and forms.

A display device includes a plurality of pixels configured to display an image and a transistor configured to control the operation of each pixel. In addition, transistors formed in the same process as the transistors provided in the pixels are also provided in a non-active area around the plurality of pixels.

Among display devices, a light emitting display device having an light emitting element in a display panel without a separate light source for compactness of the device and clear color display is considered to be a competitive application.

Meanwhile, in recent years, a display device is provided with a sensor for various purposes. All or some of the thickness of a substrate in a hole region is removed such that the sensor can easily collect external light.

### SUMMARY

Embodiments of the present disclosure provide a light emitting display device capable of preventing the influence of external air through a hole in a substrate and improving the reliability of a subpixel by changing the configuration between the hole and the subpixel at an active area on the substrate.

Embodiments of the present disclosure provide a light emitting display device wherein reliability of an element including a transistor is improved.

Embodiments of the present disclosure provide a light emitting indicator apparatus capable of preventing external light through a hole in a substrate from affecting the configuration of an element surrounding the hole.

Embodiments of the present disclosure provide a display device manufactured through a process optimized by reducing manufacturing process costs, shortening manufacturing process time, reducing production energy, and reducing greenhouse gas emissions.

A light emitting display device according to an embodiment of the present disclosure may include a substrate including an active area having a hole and a non-active area to surround the active area, a plurality of subpixels provided in the active area to be spaced apart from the hole by more than a first distance, a transistor at each of the plurality of subpixels, a light emitting element at each of the plurality of subpixels, the light emitting element comprising a first electrode connected to the transistor, a second electrode opposite the first electrode, and an intermediate layer between the first and second electrodes, an intermediate layer disconnection structure within the first distance, the intermediate layer disconnection structure surrounding the hole and having an undercut shaped section, an encapsulation layer disposed on the light emitting element, the encapsulation layer to cover at least the intermediate layer disconnection structure within the first distance; a touch sensor on the encapsulation layer: and a self-assembled layer on an upper surface of at least one of a plurality of inorganic layers included in the encapsulation layer and the touch sensor.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a plan view showing a light emitting display device according to an embodiment of the present disclosure.

FIG. 2 is an enlarged view of area A of FIG. 1.

FIG. 3 is a circuit diagram showing a subpixel of FIG. 1.

FIG. 4 is a sectional view of the light emitting display device according to the embodiment of the present disclosure, taken along line I-I′ of FIG. 2.

FIG. 5 is a sectional view of a light emitting display device according to another embodiment of the present disclosure, taken along line I-I′ of FIG. 2.

FIG. 6 is a view showing the internal structure of a self-assembled layer of FIG. 4 or 5.

FIG. 7 is an enlarged sectional view showing area B of FIG. 4.

FIG. 8 is an enlarged sectional view showing area C of FIG. 4.

FIG. 9 is a graph showing conductivity of each self-assembled layer over time.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.
In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a display device according to the present disclosure will be described with reference to the accompanying drawings and embodiments.

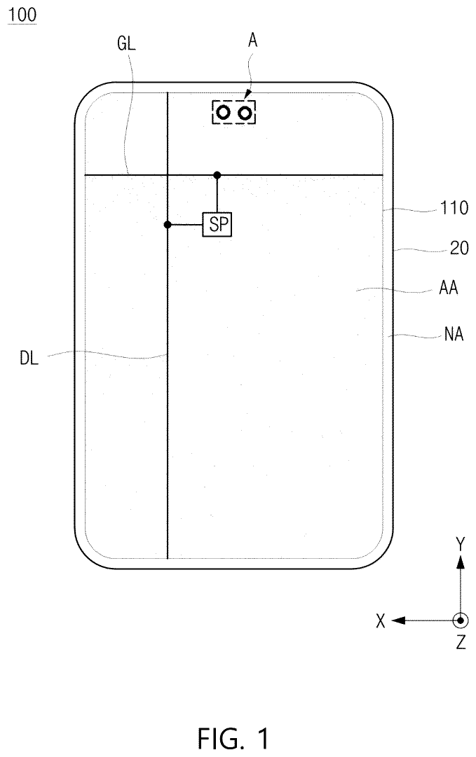

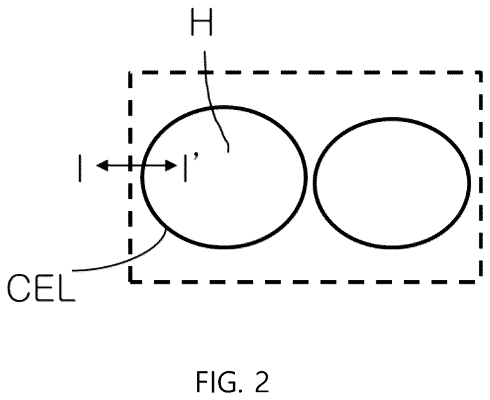

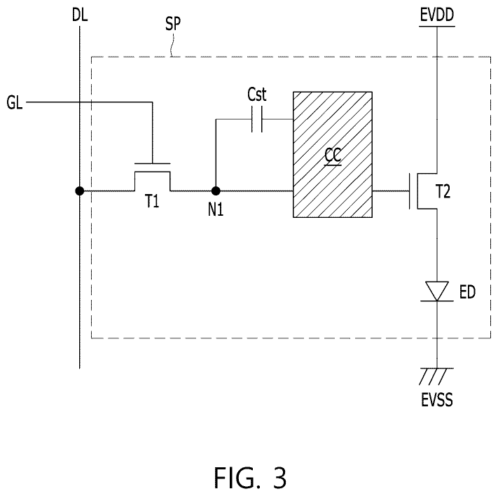

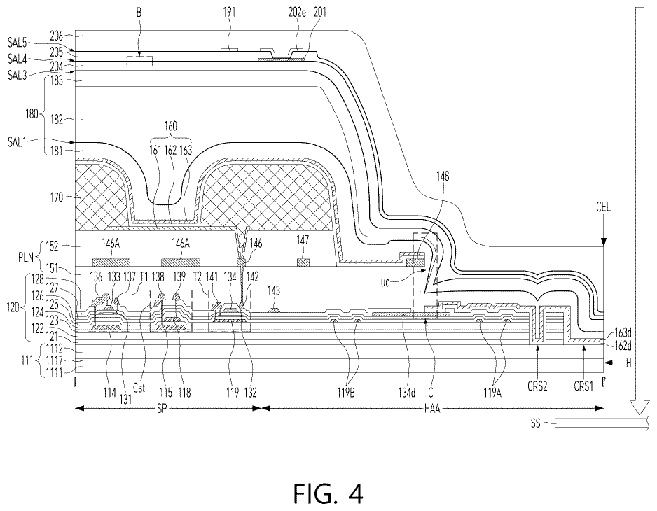

FIG. 1 is a plan view showing a light emitting display device according to an embodiment of the present disclosure. FIG. 2 is an enlarged view of area A of FIG. 1. FIG. 3 is a circuit diagram showing a subpixel of FIG. 1. FIG. 4 is a sectional view of the light emitting display device according to the embodiment of the present disclosure, taken along line I-I′ of FIG. 2.

Referring to FIG. 1, the display device 100 according to the embodiment of the present disclosure includes a display panel 110 including an active area AA and a non-active area NA and a cover member 20 disposed on the display panel 110.

The cover member 20 may be disposed on the display panel 110 so as to cover a front surface of the display panel 110 and may protect the display panel 110 from external impact. An edge portion of the cover member 20 may have a curvature portion or a curved surface portion bent in a direction toward a rear surface of the display device 100 (−Z axis direction). As a result, the cover member 20 may be disposed so as to cover a side surface area of the display panel 110 disposed on the rear surface, whereby the display panel 110 may be protected from external impact at not only the front surface but also the side surface of the display device 100.

The active area AA of the display device 100 may be an area for displaying an image, and an area other than the active area AA may be referred to as the non-active area NA. The active area AA and the non-active area NA of the display device 100 may be equally applied to the display panel 110.

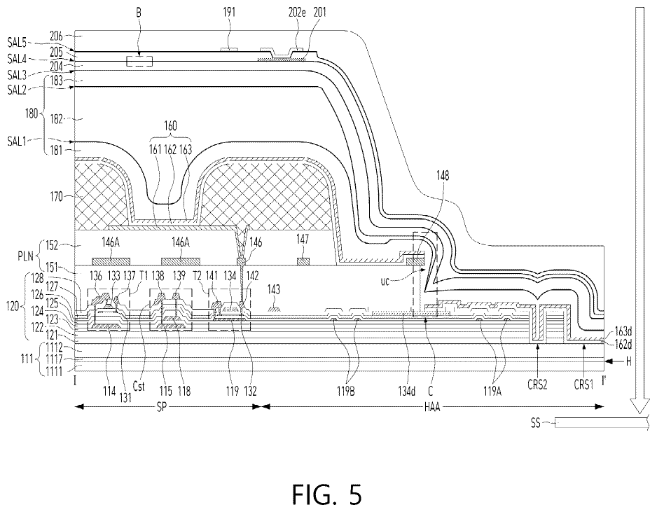

The display device includes a substrate 111 (see FIGS. 4 and 5) having both the active area AA and the non-active area NA. A plurality of data lines DL extending in a first direction and a plurality of gate lines GL extending in a second direction intersecting the first direction may be disposed in the active area AA on the substrate.

The areas delimited by the intersection of the data line DL and the gate line GL may each constitute one subpixel SP. One subpixel SP may be defined as the area in which an emissive portion is disposed, and is not limited to the area delimited by the intersection of the data line DL and the gate line GL. That is, the emissive portion may intersect the data line DL and/or the gate line GL.

Each subpixel SP may be implemented to emit, for example, white light (W) equally across the subpixels, or red light (R), green light (G), or blue light (B) differently across the subpixels. If the subpixel SP emits white light, a color filter layer may be further provided on the side from which the light emits from the subpixel SP to represent a color corresponding to each subpixel.

As shown in FIG. 2, a hole H may be provided in a part of the active area AA the substrate 111 (FIG. 4 or 5) corresponding to a camera or a sensor SS (FIG. 4). The sensor may include a variety of sensors SS, such as an image sensor, an infrared sensor, and an ultraviolet sensor. The camera may be provided in plural for various purposes. All or some of the thickness of the substrate 111 is removed so as to correspond to the hole H. The hole H in the substrate 111 may overlap the camera or the sensor SS. The camera or the sensor is located under the substrate 111, at least a light receiving portion of the camera or the sensor corresponds to the hole H, and a module of the camera or the sensor surrounding the light receiving portion may overlap the substrate 111.

After the configuration of an array on the substrate 111, both the substrate 111 corresponding to the hole H and the configuration on the substrate 111 may be removed by irradiating an end line CEL of the hole with a laser.

The end line CEL of the hole H is located at the boundary between the area where the hole H is disposed and the substrate 111 is removed and the area of the substrate 111 provided outside the hole H.

Meanwhile, the hole H of the substrate 111 is provided in the active area AA of the substrate 111, and the subpixels SP are disposed around the periphery spaced a first distance HAA from the end line CEL of the hole H. The plurality of subpixels provided in the active area are spaced apart from the hole by more than a first distance HAA from the end line CEL of the hole H.

In the display device according to the embodiment of the present disclosure, as shown in FIGS. 2 and 4, the subpixels SP may be disposed at a first distance HAA (FIG. 4) apart from the end line CEL of the hole H to prevent impact generated when the substrate 111 and the configuration on the substrate 111 are removed from the region of the hole H from propagating to the subpixels SP.

Within the first distance HAA (FIG. 4), an undercut shaped section UC is provided as intermediate layer disconnection structure to prevent direct exposure of an intermediate layer 162 at the end line CEL of the hole after the hole H is formed.

The undercut shaped section UC (FIG. 4) may, for example, be provided with a protrusion pattern 148 on a first planarization layer 151. Here, the first planarization layer 151, the configuration under the protrusion pattern 148, has an undercut shape UC. In the case of having the undercut shaped section UC, in the process of deposition of an intermediate layer material, the intermediate layer material having a strong straightness and poor step coverage is not stacked in the undercut shaped section UC where the protrusion pattern 148 is covered, and a break occurs between the intermediate layer 162 deposited on the protrusion pattern 148 and an intermediate layer dummy layer 162d around the undercut shape UC. The intermediate layer 162 includes a plurality of organic material layers, each of which may be deposited on the substrate through a vapor deposition process. The vapor deposition process is accomplished by placing a source of vapor deposition material in a lower part of a chamber, holding a substrate having a deposition surface on which the disposition material is to be deposited in an upper part of the chamber, and supplying the deposition material to the substrate in a vapor phase. Since vapor deposition has lower step coverage than sputtering or printing processes, deposition is not well performed on a screen structure such as the protrusion pattern, whereby the structure such as the protrusion pattern 148 may be formed prior to the deposition process to ensure that the intermediate layer is disconnected in a certain area.

The light emitting display device according to the embodiment of the present disclosure has the intermediate layer disconnection structure within a first distance from the end line CEL of the hole H, thereby separating the intermediate layer 162 of the subpixels SP from the end line CEL of the hole H exposed to the outside, and preventing moisture penetration deterioration of the intermediate layer 162 (FIG. 4).

As shown in FIGS. 1 to 4, the light emitting display device 100 according to the embodiment of the present disclosure includes a substrate 111 (FIG. 4) including an active area AA having a hole and a non-active area NA surrounding the active area AA and a plurality of subpixels SP provided in the active area AA so as to be spaced apart from the hole by a first distance HAA.

As shown in FIGS. 3 and 4, each of the plurality of subpixels SP includes transistors T1 and T2.

Each of the plurality of subpixels SP includes a light emitting element 160 (ED) including a first electrode 161 connected to the transistor T2, a second electrode 163 opposite the first electrode 161, and an intermediate layer 162 disposed between the first and second electrodes 161 and 163 (FIG. 4).

Each subpixel includes an intermediate layer disconnection structure (area C in FIG. 4) configured to surround the hole H within the first distance HAA and having a section of an undercut shape UC.

In addition, each subpixel includes an encapsulation layer 180 disposed on the light emitting element 160 (ED) while covering at least the intermediate layer disconnection structure within the first distance HAA and touch sensor including at least one touch metal line layer 191, 201, and 202e on the encapsulation layer 180.

The light emitting display device according to the embodiment of the present disclosure may include self-assembled layers SAL1, SAL3, SAL4, and SAL5 provided on at least one of a plurality of inorganic layers 181, 183, 204, and 205 included in the encapsulation layer 180 and the touch sensor (FIG. 4).

Here, before describing the plurality of inorganic layers 181, 183, 204, and 205 used by the self-assembled layers SAL1, SAL3, SAL4, and SAL5 as forming surfaces, the structure of the light emitting display device will first be described with reference to FIGS. 3 and 4.

A subpixel SP is disposed between a gate line GL and a data line DL that intersect each other, as shown in FIG. 3, and may include a first transistor T1, a second transistor T2, a storage capacitor Cst, a compensation circuit CC, and a light emitting element ED.

For example, the first transistor T1 may be a switching transistor, and the second transistor T2 may be a driving transistor.

The first transistor T1 is electrically connected to a data line DL and is electrically connected to a first node N1. A gate electrode of the first transistor T1 is electrically connected to a gate line GL. The first transistor T1 transmits a data signal supplied via the data line DL to the first node N1 in response to a scan signal supplied via the gate line GL.

The storage capacitor Cst is electrically connected to the first node N1 to store voltage applied to the first node N1.

The second transistor T2 receives a high potential drive voltage EVDD, and is electrically connected to a first electrode (e.g., an anode) of the light emitting element ED. The second transistor T2 may control the amount of driving current flowing to the light emitting element ED in response to voltage applied to the gate electrode.

A semiconductor layer of each of the first transistor T1 and the second transistor T2 may include an oxide semiconductor material, such as indium-gallium-zinc-oxide (IGZO).

The light emitting element ED outputs light corresponding to the driving current supplied from the second transistor T2. The light emitting element ED may output light corresponding to any one of red, green, blue, and white.

The light emitting element ED may include a first electrode, an intermediate layer disposed on the first electrode, and a second electrode to which a common voltage EVSS is supplied. The intermediate layer includes a light emitting layer and various functional layers, and may be configured to emit the same color of light on a pixel-by-pixel basis, such as white light, or may be configured to emit different colors on a subpixel-by-subpixel basis, such as red, green, or blue light. The functional layers may include a hole injection layer, a hole transport layer, an electron transport layer, an electron injection layer, and a charge generation layer. The intermediate layer may include a plurality of stacks, wherein the plurality of stacks may have a charge generation layer between adjacent stacks to facilitate the supply of holes and electrons to both stacks. Each of the plurality of stacks may include at least one emissive layer, a hole transport layer, and an electron transport layer.

The first electrode may function as an anode, and the second electrode may function as a cathode. The light emitting element ED is substantially the same as a light emitting element 160 (see FIG. 4) to be described later.

The compensation circuit CC may be provided in a first subpixel SP1 to compensate for a threshold voltage of the second transistor T2. The compensation circuit CC may include one or more transistors. The compensation circuit CC may include one or more transistors and capacitors, and may be variously configured depending on a compensation method. The subpixel including the compensation circuit CC may include various structures, such as 3T1C, 4T2C, 5T2C, 6T1C, 6T2C, 7T1C, and 7T2C. For example, a plurality of transistors may be electrically connected between the second transistor T2 and the light emitting element ED.

FIG. 3 shows the configuration in which the second transistor T2 and the light emitting element ED are directly connected to each other, but the embodiment of the present disclosure is not limited thereto. Depending on the form of the compensation circuit CC, the light emitting element ED may further include another transistor or a compensation capacitor between the light emitting element ED and the second transistor T2 generating the drive current.

The light emitting display device according to the embodiment of the present disclosure includes a plurality of subpixels SP provided in the active area AA spaced apart from the hole H by a first distance HAA, transistors T1 and T2 provided in each of the plurality of subpixels SP, and an light emitting element 160 connected to at least one of the transistors T1 and T2.

The light emitting element 160 includes a first electrode 161, an intermediate layer 162, and a second electrode 163 (FIG. 4).

An emissive portion of the light emitting element 160 is provided in an opening of a bank 170, wherein the bank 170 may include a light shielding bank made of a light shielding organic material and/or a transparent bank made of a transparent organic material.

If the bank 170 includes a light shielding bank, the bank may screen a non-emissive portion between adjacent subpixels SP and prevent light from each of the subpixels SP from straying into neighboring subpixels SP and causing mixing. In addition, when external light enters from above, the bank may reduce or prevent reflection of the external light from the surfaces of the first and second electrodes 161 and 163 overlapping the bank 170 to prevent external light visibility (FIG. 4).

The substrate 111 may be made of a flexible material, which may be easily removed upon laser irradiation to form the hole H. In an example, the substrate 111 may include first and second organic layers 1111 and 1112 overlapping each other with an inorganic interlayer insulating layer 1117 therebetween. The inorganic interlayer insulating layer 1117 may have the function of blocking the transfer of moisture or impurities between the first and second organic layers 1111 and 1112. The inorganic interlayer insulating layer 1117 may be formed on the first organic layer 1111, and may be partially patterned. The inorganic interlayer insulating layer 1117 may include at least one of a silicon nitride layer, a silicon oxide layer, and a silicon oxynitride layer (FIG. 4).

The first and second organic layers 1111 and 1112 may include, for example, polyimide. In addition to polyimide, the first and second organic layers 1111 and 1112 may include different organic layers.

The substrate 111 may include one of the first and second organic layers 1111 and 1112 as polyethylene terephthalate (PET) and the other as polyimide.

In another example, the substrate 111 may include a flexible, thin glass material.

The substrate 111 serves to support and protect the components of the light emitting display device disposed thereon.

In the active area AA and the non-active area NA of the substrate 111, a plurality of laminated insulating layers 120 (121, 122, 123, 124, 125, 126, 127, and 128) and planarization layers 151 and 152 are disposed, whereby active layers 131 and 132 and gate electrodes 133 and 134 of the transistors T1 and T2 are insulated from each other, the gate electrodes 133 and 134 and source-drain electrodes 137, 141 and 142 are insulated from each other, and a first storage electrode 115 and a second storage electrode 118 constituting the storage capacitor Cst are insulated from each other (FIG. 4).

In an example, the first transistor T1 includes a first light shielding pattern 114, a first active layer 131, a first gate electrode 133, and a source-drain electrode 137. The first light shielding pattern 114 may be connected to the first gate electrode 133 disposed on the first active layer 131 via a connection electrode 136 and function as a double gate. In this case, the same gate voltage is applied to the first light shielding pattern 114 and the first gate electrode 133.

In an example, the second transistor T2 includes a second light shielding pattern 119, a second active layer 132, a second gate electrode 134, a first source-drain electrode 141, and a second source-drain electrode 142.

The storage capacitor Cst includes a first storage electrode 115 and a second storage electrode 118 overlapping each other with a fourth insulating layer 124 therebetween. The first storage electrode 115 and the second storage electrode 118 may be connected to first and second connection electrodes 138 and 139 configured as metal layers located on the same layer as the source-drain electrodes 137, 141, and 142 of the first and second transistors T1 and T2 thereon.

The second transistor T2 may be connected to the first electrode 161 of the light emitting element 160 (ED in FIG. 3) via the connection electrode 146.

As shown in FIG. 4, metal line layers 119A, 119B, 143, 147, and 134d may be further provided within the first distance HAA from the end line CEL of the hole H in a shape parallel to the end line CEL of the hole. Among the metal line layers 119A, 119B, 143, 147, and 134d, the metal line layer 134d, to which a low potential voltage VSS or a high potential voltage VDD is applied, may be wider than the other metal line layers.

The metal line layers 119A, 119B, 143, 147, and 134d may be located on the same layer as any one of the light shielding patterns 114 and 119 of the transistors T1 and T2, the active layers 131 and 132, the gate electrodes 133 and 134, the source-drain electrodes 137, 141, and 142, and the connection electrode 146.

Meanwhile, a metal layer 146A overlapping the first transistor T1 and the storage capacitor Cst may be further provided on the same layer as the connection electrode 146. The metal layer 146A may prevent the operation of the first transistor T1 or the storage capacitor Cst from causing electrical interference to the upper light emitting element 160 (FIG. 4).

For example, the insulating layer 120 may include a first insulating layer 121, a second insulating layer 122, a third insulating layer 123, a fourth insulating layer 124, a fifth insulating layer 125, a sixth insulating layer 126, a seventh insulating layer 127, and an eighth insulating layer 128. The insulating layer 120 may include an inorganic insulating material.

Meanwhile, crack prevention portions CRS1 and CRS2, in which all or some of the first to eighth insulating layers 121 to 128 are removed, may be provided adjacent to the end line CEL of the hole H. Each of the crack prevention portions CRS1 and CRS2 may have a circular shape surrounding the hole H in plan and a larger diameter than the hole H. The crack prevention portions CRS1 and CRS2 may block or disperse impact propagating to the vicinity of the end line CEL of the hole H upon hole formation from being transmitted horizontally via the inorganic insulating layer.

The first insulating layer 121 is disposed in the active area AA and the non-active area NA of the substrate 111. The first insulating layer 121 may be referred to as a buffer layer and may perform the same function as a buffer layer known in the art. The first insulating layer 121 may be disposed on the substrate 111 to protect structures located on the substrate 111 from moisture permeating through the substrate 111 and to planarize the surface of the substrate 111. The first insulating layer 121 may include a plurality of inorganic insulating layers.

The first insulating layer 121 may extend to an edge the non-active area NA of the substrate 111 to prevent permeation of moisture from the edge of the substrate 111. The first insulating layer 121 may be constituted by a single inorganic layer or a plurality of alternately stacked inorganic layers.

For example, the first insulating layer 121 may include at least one of a silicon oxide (SiOₓ) layer, a silicon nitride (SiNₓ) layer, and a silicon oxynitride (SiOₓN_{y}) layer, or a multilayer layer formed by stacking the inorganic layers.

The second insulating layer 122 may be disposed on the first insulating layer 121. The second insulating layer 122 may function, for example, as a second buffer layer. A polysilicon-type transistor having an active layer made of crystalline silicon may be included as a transistor provided on the substrate 111. In this case, the second insulating layer 122 may stabilize and planarize a formation surface of the active layer including crystalline silicon. The second insulating layer 122 may include an inorganic layer, such as a silicon oxide (SiOₓ) layer, a silicon nitride (SiNₓ) layer, or a multilayer layer thereof.

The third insulating layer 123 may be provided on the second insulating layer 122. The third insulating layer 123 may be used as a gate insulating layer of a transistor including crystalline silicon as an active layer.

The first light shielding pattern 114 of the first transistor T1 and the first storage electrode 115 of the storage capacitor Cst may be provided on the third insulating layer 123. Each of the first light shielding pattern 114 and the first storage electrode 115 may be made of, for example, a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

The fourth insulating layer 124 may be disposed on the third insulating layer 123. The fourth insulating layer 124 functions as an insulator between the first and second storage electrodes 115 and 118, and may also function as an interlayer insulating layer of a transistor including polycrystalline silicon as an active layer.

The fourth insulating layer 124 may include an inorganic material. The inorganic material may include, for example, a silicon nitride (SiNₓ) layer.

The second storage electrode 118, which is made of a conductive metal material, may be formed on the fourth insulating layer 124. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

Each of the first storage electrode 115 and the second storage electrode 118 may be a single layer, or may have a structure in which a plurality of different metal materials is stacked.

The fifth insulating layer 125 may be disposed on the fourth insulating layer 124.

The second light shielding pattern 119 of the second transistor T2, which is made of a conductive metal material, may be disposed on the fifth insulating layer 125. The conductive metal material may, for example, be made of metal. The second light shielding pattern 119 may be made of a single metal, and may also be made of two or more metals or two or more metal alloys. In addition, the second light shielding pattern 119 may have a single layer structure or a multilayer structure.

The sixth insulating layer 126 may be disposed on the fifth insulating layer 125 so as to cover the second light shielding pattern 119.

The fifth insulating layer 125 and the sixth insulating layer 126 are located under the first and second active layers 131 and 132 and may function as buffer layers.

The first and second transistors T1 and T2 may include first and second active layers 131 and 132, each of which is an oxide semiconductor layer. When the active layer is formed including an oxide semiconductor layer, off characteristics may be stabilized and a certain degree of carrier mobility may be secured.

The fifth insulating layer 125 and the sixth insulating layer 126 may serve to planarize forming surfaces of the first and second active layers 131 and 132 including the oxide semiconductor layer disposed thereon.

Each of the fifth insulating layer 125 and the sixth insulating layer 126 may include an inorganic material. The inorganic material may include, for example, a silicon oxide (SiOₓ) layer or a multilayer layer formed by stacking inorganic layers.

No hydrogen particles are discharged during heat treatment, and therefore it is possible to prevent a decrease in reliability of the first and second active layers 131 and 132, each of which is an oxide semiconductor layer, disposed on the fifth and sixth insulating layers 125 and 126 so as to be adjacent to each other due to hydrogen particles.

Each of the first and second active layers 131 and 132 may include an oxide semiconductor material. The oxide semiconductor material may include a combination of at least one of zinc (Zn), indium (In), gallium (Ga), tin (Sn), and titanium (Ti) and an oxide. In some cases, a highly conductive metal, such as iron (Fe), may be further included in the oxide semiconductor material to increase mobility.

More specifically, the oxide semiconductor material constituting each of the first and second active layers 131 and 132 may be, for example, zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), or iron-indium-zinc oxide (FIZO).

While each of the first and second active layers 131 and 132 include an oxide semiconductor in the shown example, the embodiment of the present disclosure is not limited thereto. At least one of the transistors provided in the subpixel SP may include crystalline silicon.

The seventh insulating layer 127, which functions as a gate insulating layer, may be disposed between the first and second active layers 131 and 132 and the first and second gate electrodes 133 and 134. The seventh insulating layer 127 may be disposed entirely between the first and second active layers 131 and 132 and the first and second gate electrodes 133 and 134, as shown, or may be selectively disposed only in the channel areas of the first and second active layers 131 and 132.

The seventh insulating layer 127 is made of an inorganic insulating material and may include, for example, a silicon oxide (SiOₓ) layer, a silicon nitride (SiNₓ) layer, or a multilayer layer formed by stacking inorganic layers.

The areas overlapping the first and second gate electrodes 133 and 134 that are undoped may be used as the channel areas of the first and second active layers 131 and 132.

The doped areas of the first and second active layers 131 and 132 may be provided respectively by using the first and second gate electrodes 133 and 134 as masks. The doped areas of the first and second active layers 131 and 132 correspond to areas located on both sides of the first and second gate electrodes 133 and 134, and the doped areas of the first and second active layers 131 and 132 may be subsequently connected to spaced apart source-drain electrodes 137, 141, and 142 and function as conductive source-drain areas.

The first and second gate electrodes 133 and 134 and the metal line layer 134d, each of which is made of a conductive metal material, may be provided on the seventh insulating layer 127. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). Each of the first and second gate electrodes 133 and 134 and the metal line layer 134d may have a multilayer layer structure including at least two conductive metal materials.

The eighth insulating layer 128 may be disposed on the first and second gate electrodes 133 and 134 and the metal line layer 134d. The eighth insulating layer 128 may cover the top and the side of each of the first and second gate electrodes 133 and 134, and may expose a part of the metal line layer 134d disposed within the first distance HAA.

The eighth insulating layer 128 may be constituted by a single inorganic layer or a plurality of stacked inorganic layers. At least one of a silicon oxide (SiOₓ) layer, a silicon nitride (SiNₓ) layer, and a silicon oxynitride (SiOₓN_{y}) layer may be selected as the inorganic layer.

The source-drain electrode 137 of the first transistor T1, the connection electrode 136 connecting the first light shielding pattern 114 of the first transistor T1 and the first gate electrode 133, and the first source-drain electrode 141 and the second source-drain electrode 142 connected to the second active layer 132 of the second transistor T2 may be disposed on the eighth insulating layer 128 through a conductive metal. The first and second connection electrodes 138, 139 connected respectively to the first storage electrode 115 and the second storage electrode 118 are disposed. In addition, the metal line layer 143 parallel to the end line CEL of the hole may be provided within the first distance HAA.

In the first transistor T1 shown in FIG. 4, for example, the connection electrode 136 and the source-drain electrode 137 are illustrated above the first gate electrode 133 corresponding to both sides of the first active layer 131. However, the first transistor T1 of FIG. 4 is illustrated along one axis. Another source-drain electrode different from the source-drain electrode 137 of the first transistor T1 may be further disposed along another axis, at a position different from the shown area in FIG. 4 and another source-drain electrode is connected to the first active layer where another source-drain electrode overlaps the first active layer 131. The first gate electrode 133 and the first light shielding pattern 114 may be connected to each other by the connection electrode 136. And the source-drain electrode 137 and another source-drain electrode may be connected to the first active layer 131 at both sides of the first gate electrode 133 along another axis.

In the second transistor T2, the first source-drain electrode 141 and the second source-drain electrode 142 may be disposed spaced apart from each other with the second gate electrode 134 therebetween. In this case, the first source-drain electrode 141 and the second source-drain electrode 142 and the second gate electrode 134 may be disposed on different layers.

Meanwhile, the first source-drain electrode 141 may extend to an area away from the second active layer 132 of the second transistor T2 so as to be connected to the second light shielding pattern 119 thereunder. In this case, the potential of the second light shielding pattern 119 may be stabilized.

Each of the source-drain electrode 137, the connection electrode 136, the first and second connection electrodes 138 and 139, the first source-drain electrode 141, and the second source-drain electrode 142 may be made of a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). Each of the source-drain electrode 137, the connection electrode 136, the first and second connection electrodes 138 and 139, the first source-drain electrode 141, and the second source-drain electrode 142 may have a multilayer layer structure including at least two conductive metal materials.

The first source-drain electrode 141 and the second source-drain electrode 142 are connected to both sides of the channel area of the second active layer 132.

The channel area of each of the first and second active layers 131 and 132 may be an undoped intrinsic area, which may be the area where carriers move when voltage is applied to the transistors T1 and T2.

Each of the source-drain electrode 137, the first source-drain electrode 141, and the second source-drain electrode 142 may be directly connected to the first and second active layers 131 and 132 via contact holes provided in the seventh insulating layer 127 and the eighth insulating layer 128.

The metal line layer 143 may further be provided within the first distance HAA on the same layer as the source-drain electrode 137, the first source-drain electrode 141, and the second source-drain electrode 142.

A first planarization layer 151 for protecting the first and second transistors T1 and T2 and the storage capacitor Cst may be provided on the connection electrode 136, the source-drain electrode 137, the first source-drain electrode 141, the second source-drain electrode 142, and the first and second connection electrodes 138 and 139. The first planarization layer 151 may be disposed over a part of the first distance HAA and spaced apart from the end line CEL of the hole by a certain distance. This is so that the first planarization layer 151 including the organic material is not in direct contact with the outside air through the hole H. The first planarization layer 151 may be disposed to directly contact the upper surface of the metal line layer 134d exposed by the eighth insulating layer 128 within the first distance HAA. The first planarization layer 151 located on the metal line layer 134d within the first distance HAA may function to support the subsequently formed protrusion pattern 148.

A connection electrode 146 may be further provided on the first planarization layer 151, and may be connected to the second source-drain electrode 142 via a contact hole in the first planarization layer 151. The connection electrode 146 may be made of, for example, a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

A protrusion pattern 148 that protrudes farther than the top of the first planarization layer 151 and a metal line layer 147 that is parallel to the end line CEL of the hole may be provided on the same layer as the connection electrode 146. The first planarization layer 151 under the protrusion pattern 148 may be disposed with sufficient thickness to stably support the protrusion pattern 148 and prevent the protrusion pattern 148 from deviating or separating. The protrusion pattern 148 may be made of the same material as the connection electrode 146 and the first and second source-drain electrodes 141 and 142. For example, each of the protrusion pattern 148, the connection electrode 146, and the first and second source-drain electrodes 141 and 142 may be made of a triple laminated metal layer, such as Ti/Al/Ti.

The area of the first planarization layer 151 that is more recessed than the protrusion pattern 148 is the area of the undercut shape UC, and may be provided in the area where the first planarization layer 151 is removed.

In addition, in the same process as the connection electrode 146, a metal layer 146A overlapping the first transistor T1 and the storage capacitor Cst may be further provided.

A second planarization layer 152 may be further disposed on the metal layer including the connection electrodes 146. The second planarization layer 152 is spaced apart from the protrusion pattern 148 and is disposed to expose the protrusion pattern 148. This is so that, when the intermediate layer 162 is subsequently formed, the protrusion pattern 148 disconnects the intermediate layer.

A first electrode 161 may be further provided on the second planarization layer 152, and may be connected to the connection electrode 146 via a contact hole in the second planarization layer 152.

Each of the first planarization layer 151 and the second planarization layer 152 is made of an organic insulating material and may be functionally referred to as a planarization layer PLN.

Since the organic insulating material included in the planarization layer PLN may be relatively susceptible to moisture and other external agents compared to inorganic insulating materials, the organic insulating material may be removed from around the hole H so as to be spaced apart from the hole H to prevent direct contact with the end line CEL of the hole H.

In some cases, the connection electrode 146 may be omitted, and the planarization layer PLN may be configured as a single layer. In this case, the second source-drain electrode 142 may be directly connected to the first electrode 161.

The first electrode 161 may include, for example, a reflective electrode and may function to prevent incidence of light on the transistors T1 and T2 under the light emitting element 160. The first electrode 161 may include, for example, a structure in which a first transparent electrode, a reflective electrode, and a second transparent electrode are stacked. The second transparent electrode, which is the uppermost electrode of the first electrode 161, may be a dielectric, which may lower the barrier to hole injection at the interface with the intermediate layer 162. Here, each of the first and second transparent electrodes may be a transparent oxide electrode such as ITO or IZO. The reflective electrode may include silver, a silver alloy such as APC (Ag-Pd-Cu), aluminum, or an aluminum alloy.

A bank 170 may be provided so as to cover the edge of the first electrode 161, and an opening in the bank 170 may be defined as an emissive portion.

The bank 170 may include an organic insulating material to maintain a certain vertical thickness. The organic insulating material of the bank 170 may have a vertical thickness of, for example, 1 μm to 5 μm.

In some cases, in the same process of forming the bank 170 and the planarization layer PLN, a dam portion may be provided within the first distance HAA to prevent overflow of an organic encapsulation layer, which is subsequently formed as a liquid, around the hole H.

The light emitting element 160 includes a first electrode 161, an intermediate layer 162, and a second electrode 163. After forming the first electrode 161, the bank 170 may be formed.

A spacer maybe further provided on the bank 170. The spacer may be locally disposed on a part of an upper surface of the bank 170, rather than on the entirety of the upper surface of the bank 170, to prevent collapse of the bank 170 under the spacer or a lower configuration when a deposition mask is applied to the substrate 111 during deposition of the intermediate layer 162. The spacer and the bank 170 may be made of the same material.

The intermediate layer 162 and the second electrode 163 are sequentially disposed on the substrate 111 having the bank 170 and the intermediate layer disconnection structure (area C in FIG. 4).

The intermediate layer 162 may include a plurality of functional layers along with the light emitting layer. For example, the intermediate layer 162 may include a hole injection layer, a hole transport layer, a light emitting layer, an electron transport layer, and an electron injection layer. The intermediate layer 162 may be formed in a tandem structure including a plurality of stacks, each including a hole transport layer, a light emitting layer, and an electron transport layer, and a charge generating layer provided between the stacks. The charge generating layer may include, for example, an n-type charge generating layer and a p-type charge generating layer.

The subpixels SP represent individual colors through the light emitting elements 160, and the light emitting layer may be patterned and disposed on each subpixel SP using a deposition mask including an opening corresponding to the emissive portion for each subpixel.

Functional layers other than the light emitting layer, such as a hole injection layer, a hole transport layer, an electron transport layer, an electron injection layer, and a charge generation layer, are commonly included in the plurality of subpixels. In addition, the second electrode 163 may also be commonly included in the plurality of subpixels. The common layers are formed through a common mask having an opening common to the plurality of subpixels without disconnection per subpixel, and a forming material of each layer is provided on the substrate through the common opening. In the light emitting display device according to the embodiment of the present disclosure, since the intermediate layer disconnection structure (area C in FIG. 4) has an undercut shaped section UC, the common layer may be separated from the undercut shaped section. In the deposition process for the formation of the common layer, the common layer forming material is vaporized and deposited on the substrate 111, and the deposited material may be formed consistently in a straight direction, but, as in the undercut shape, formation of the common layer on the side of the first planarization layer 151 screened by the protrusion pattern 148 protruding from the first planarization layer 151 and the unexposed surface of a part of the metal line layer 134d is difficult, and the common layer is deposited very thinly or not deposited, resulting in disconnection.

As such, the intermediate layer 162 and the second electrode 163 are disconnected on the side surface of the protrusion pattern 148 having an undercut shaped section and the first planarization layer 151, and the intermediate layer 162 and the second electrode 163 may be separated from the intermediate layer dummy layer 162d and the second electrode dummy layer 163d remaining in the area of the end line CEL of the hole. Therefore, even if the intermediate layer dummy layer 162d is adjacent to the hole H and is permeated by moisture or oxygen entering through the hole H, this does not affect the intermediate layer 162 included in the light emitting element 160 of the subpixel SP. Therefore, the subpixel SP may reliably withstand moisture or oxygen entering through the hole H.

The second electrode 163 may be formed by thinning a transmissive electrode made of ITO or IZO or a reflective-transmissive electrode made of silver, a silver alloy, magnesium, a magnesium alloy, ytterbium (Yb), or an ytterbium alloy.

A capping layer (not shown) may be further formed on the second electrode 163 to protect the second electrode 163 of the light emitting element 160 and to increase light emission efficiency in an upward direction.

An encapsulation layer 180 may be provided on the second electrode 163 to prevent permeation of moisture into internal components and to protect the internal components from external air.

In an example, the encapsulation layer 180 may include a structure in which a first inorganic encapsulation layer 181, an organic encapsulation layer 182, and a second inorganic encapsulation layer 183 are stacked. The display device according to the embodiment of the present disclosure is not limited to the configuration shown. Here, the organic encapsulation layer 182 has a greater thickness than the first and second inorganic encapsulation layers 181 and 183, which may make laser cutting along the end line CEL of the hole H difficult when the organic encapsulation layer 182 remains around the hole H. In addition, if the organic encapsulation layer 182 extends to the hole H, the organic encapsulation layer 182 may be directly affected by the hole H through which the outside air directly enters.

Therefore, the organic encapsulation layer 182 is located spaced apart from the end line CEL of the hole by a certain distance. While the organic encapsulation layer 182 has an end line around the protrusion pattern 148 in the shown example, the embodiment of the present disclosure is not limited thereto. For example, the end of the organic encapsulation layer 182 may be spaced farther away from the end line CEL of the hole than the protrusion pattern 148. In this case, the organic encapsulation layer 182 may not overlap the protrusion pattern 148.

In some cases, an encapsulation substrate, such as glass, may be included in place of the encapsulation layer 180. An adhesive layer may be further provided between the encapsulating substrate and the light emitting element 160 facing each other.

Meanwhile, FIG. 4 shows a configuration in which a touch sensor including a first touch metal line layer 201 and a second touch metal line layer 202e and 191 is formed on the encapsulation layer 180.

The touch sensor may be disposed on the encapsulation layer 180 in the active area AA to sense touch input. The touch sensor may detect external touch information using a user's finger or a touch pen. The touch sensor may include a touch buffer layer 204, a first touch metal line layer 201, a touch intermediate insulating layer 205, a second touch metal line layer 191 and 202e, and an upper touch protective layer 206.

Each of the touch buffer layer 204 and the touch intermediate insulating layer 205 may be made of an inorganic material such as silicon nitride (SiNₓ), silicon oxide (SiOₓ), or silicon oxynitride (SiONₓ), but the embodiment of the present disclosure is not limited thereto.

In the touch sensor, the first touch metal line layer 201 and the second touch metal line layer 202e, which are located on different layers, may be connected to each other and used as a first touch sensor Tx. Another second touch metal line layer 191 separated from the second touch metal line 202e may be electrically spaced apart from the first touch sensor Tx and used as a second touch sensor Rx. A touch sensing signal may be applied to one of the first touch sensor Tx and the second touch sensor Rx, and a change due to touch may be sensed through the other.

The first and second touch sensors Tx and Rx may be disposed overlapping the bank 170. For example, the first touch sensor Tx may be disposed in the X-axis direction, and the second touch sensor Rx may be disposed in the Y-axis direction. Alternatively, the first and second touch sensors Tx and Rx may be disposed in the Y-axis and X-axis directions.

Each of the first and second touch metal line layers 201 and 202e or 191 may be made of a metal material, but the embodiment of the present disclosure is not limited thereto.

An upper protective layer 206 may be provided on the touch intermediate insulating layer 205 on which the second touch metal line layer 202e and 191 is disposed. The upper protective layer 206 may be made of an organic layer or a mixed organic and inorganic layer for surface planarization.

Each of self-assembled layers SAL1, SAL3, SAL4, and SAL5 included in the light emitting display device according to the embodiment of the present disclosure is a type of self-assembled monolayer, which is an organic material having a nanoscale thickness. The self-assembled layers SAL1, SAL3, SAL4, and SAL5 cover an upper surface of an inorganic layer and cover internal pinholes of the inorganic layer, thereby preventing impurities that may enter through the internal pinholes and outgassing (area B in FIG. 4). In addition, at least one of the self-assembled layers SAL1, SAL3, SAL4, and SAL5 may be provided in an intermediate layer disconnection structure having a steep step (area C in FIG. 4), may cover a seam that may occur in the first and second inorganic encapsulation layers 181 and 183 of the intermediate layer disconnection structure, and may protect the configuration under the first and second inorganic encapsulation layers 181 and 183 from the outside.

The inorganic layers included in the encapsulation layer 180 include the first and second inorganic encapsulation layers 181 and 183. Inorganic layers included in the touch sensor may include a touch buffer layer 204 and a touch intermediate insulating layer 205.

In the light emitting display device according to the embodiment of the present disclosure, the self-assembled layers SAL1, SAL3, SAL4, and SAL5 may be provided on upper surfaces of all of the plurality of inorganic layers 181, 183, 204, and 205 on the light emitting element 160, as shown in FIG. 4, to cover defects such as pinholes or seams that occur in all of the inorganic layers.

Alternatively, in the light emitting display device according to the embodiment of the present disclosure, the first self-assembled layer SAL1 may be optionally provided on the upper surface of the first inorganic encapsulation layer 181, which is one of the plurality of inorganic layers 181, 183, 204, and 205 on the light emitting element 160. In this case, the first self-assembled layer SAL1 may cover a pinhole in the first inorganic encapsulation layer 181, and may cover a seam that occurs around the hole H or that is caused by the steep step in the light emitting display device.

Alternatively, in the light emitting display device according to the embodiment of the present disclosure, the second self-assembled layer SAL3 may be optionally provided on the upper surface of the second inorganic encapsulation layer 183, which is one of the plurality of inorganic layers 181, 183, 204, and 205 on the light emitting element 160. In this case, the second self-assembled layer SAL3 may cover a pinhole in the second inorganic encapsulation layer 183, and may cover a seam that occurs around the hole H or that is caused by the steep step in the light emitting display device.

Alternatively, in the light emitting display device according to the embodiment of the present disclosure, the third self-assembled layer SAL4 may be optionally provided on the upper surface of the touch buffer layer 204, which is one of the plurality of inorganic layers 181, 183, 204, and 205 on the light emitting element 160. The third self-assembled layer SAL4 may cover a pinhole in the touch buffer layer 204, and may cover a seam that occurs around the hole H or that is caused by the steep step in the light emitting display device.

Alternatively, in the light emitting display device according to the embodiment of the present disclosure, the fourth self-assembled layer SAL5 may be optionally provided on the upper surface of the touch intermediate insulator layer 205, which is one of the plurality of inorganic layers 181, 183, 204, and 205 on the light emitting element 160. The fourth self-assembled layer SAL5 may cover a pinhole in the touch intermediate insulator layer 205, and may cover a seam that occurs around the hole H or that is caused by the steep step in the light emitting display device.

Meanwhile, one of the first to fourth self-assembled layers SAL1, SAL3, SAL4, and SAL5 may optionally be provided, as described, or two or three thereof may be provided together. Alternatively, all four layers may be provided, as shown in FIG. 4.

Each of the self-assembled layers SAL1, SAL3, SAL4, and SAL5 is seeded on a molecular basis, with molecules first adsorbed on the surface diffusing and then forming chemical bonds with surface components. Subsequently, the molecules adsorbed on the surface undergo a diffusion process to create an island domain centered on the seed, and the seeds are laterally connected by the growth of the island domain, forming a layer.

Thus, each of the self-assembled layers SAL1, SAL3, SAL4, and SAL5 may have a chemical bonding relationship with the inorganic layers 181, 183, 204, and 205 located thereunder.

As shown in FIG. 4, each of the self-assembled layers SAL1, SAL3, SAL4, and SAL5 may have a thickness that is less or smaller than the thickness of each of the bonded inorganic layers 181, 183, 204, and 205 thereunder.

Roughly, each of the self-assembled layers SAL1, SAL3, SAL4, and SAL5 may be as thin as 1/10 to 1/1000 of the thickness of each of the inorganic layers 181, 183, 204, and 205 thereunder. Accordingly, the plurality of self-assembled layers SAL1, SAL3, SAL4, and SAL5 may not affect luminous efficacy or permeability of the light emitting display device.

Referring to FIG. 4, each of the self-assembled layers SAL1, SAL3, SAL4, and SAL5 has a first surface (lower surface) corresponding to at least one of the plurality of inorganic layers 181, 183, 204, and 205 and a second surface (upper surface) opposite to the first surface, wherein the second surface (upper surface) of the self-assembled layer may have hydrophobicity and may effectively prevent the inflow of moisture or the like from the upper surface. Here, the first surface of each of the self-assembled layers SAL1, SAL3, SAL4, and SAL5 is a lower surface of each of the self-assembled layers SAL1, SAL3, SAL4, and SAL5 in FIG. 4, and the second surface is an upper surface of each of the self-assembled layers SAL1, SAL3, SAL4, and SAL5, wherein the second surface is located closer to the outside than the first surface.

FIG. 5 is a sectional view of a light emitting display device according to another embodiment of the present disclosure, taken along line I-I′ of FIG. 2.

As shown in FIG. 5, the light emitting display device according to the other embodiment of the present disclosure further includes a fifth self-assembled layer SAL2 disposed under the second self-assembled layer SAL3 in addition to the structure of the light emitting display device of FIG. 4.

In this case, the fifth self-assembled layer SAL2 and the second self-assembled layer SAL3 are provided on the lower surface and the upper surface of the second inorganic encapsulation layer 183, respectively, and the first self-assembled layer SAL1 is provided on the upper surface of the first inorganic encapsulation layer 181. The upper and lower surfaces of the organic encapsulation layer 182 may prevent separation between the second inorganic encapsulation layer 183 and the first inorganic encapsulation layer 181 and prevent impurities in the second and first inorganic encapsulation layers 183 and 181 from affecting the organic encapsulation layer 182 or particles remaining in the organic encapsulation layer 182 from affecting the second and first inorganic encapsulation layers 183 and 181.

Here, the fifth self-assembled layer SAL2 may be formed on the upper surface of the organic encapsulation layer 182 after application of the material for the organic encapsulation layer 182 and plasticization thereof.

Hereinafter, the composition of the self-assembled layer will be described in detail.

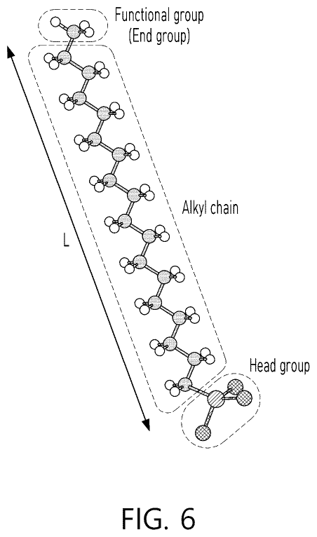

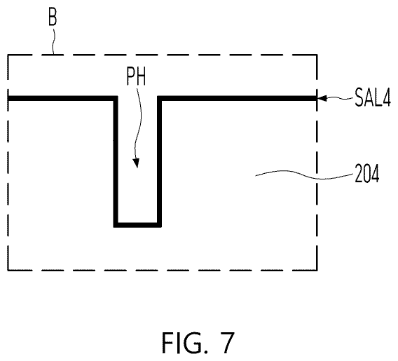

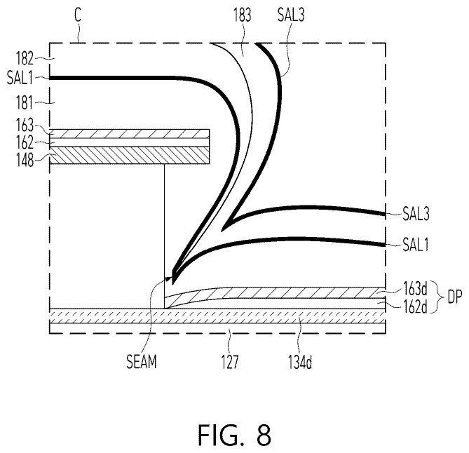

FIG. 6 is a view showing the internal structure of the self-assembled layer of FIG. 4 or 5. FIG. 7 is an enlarged sectional view showing area B of FIG. 4. FIG. 8 is an enlarged sectional view showing area C of FIG. 4.

As shown in FIG. 6, the self-assembled layer includes a head group, an alkyl chain, and a functional group (end group).

The head group is located on one side of the alkyl chain and the functional group is located on the other side of the alkyl chain.

Here, the head group is on the side facing an inorganic layer to be formed, and may be bonded with a component of the inorganic layer.

The head group of the self-assembled layer may include at least one of a —COOH group, a —SiH₃ group, a —SiCl₃ group, and a —SiF₃ group. The head group of the self-assembled layer has bonding properties with an inorganic layer located thereunder, in particular, an inorganic insulating layer such as a silicon nitride layer or a silicon oxide layer.

The head group of the self-assembled layer covalently bonds with components on the surface of the inorganic layer and has excellent inter-layer bonding with the inorganic layer.

In addition, the alkyl chain, which is the central component of the self-assembled layer, has the property of packing adjacent molecules, resulting in excellent thermal stability of the layer.

Here, the alkyl chain of the self-assembled layer may have a bond length L from the upper surfaces of the inorganic layer 181, 183, 204, and 205 in a thickness direction.

The alkyl chain may have 2 to 30—CH₂— bonds and may be adjustable in thickness or height. The thickness of the self-assembled layer, adjusted for the number of bonds in the alkyl chain, may be 1 nm to 50 nm.

The functional group (end group) of the self-assembled layer may be a —CH₃ group or a —CF₃ group. In the light emitting display device according to the embodiment of the present disclosure, the functional group is located on the outermost side of the self-assembled layer. The self-assembled layer protects the configuration under the self-assembled layer from external air such as moisture or oxygen, wherein the functional group located on the surface thereof is hydrophobic.

In an example, the self-assembled layer may be alkyltrichlorosilane in which the functional group is hydrophobic.

The self-assembled layer is seeded on a molecular basis, with molecules first adsorbed on the surface of an inorganic layer diffusing and then forming chemical bonds with surface components. Subsequently, the molecules adsorbed on the surface undergo a diffusion process to create an island domain centered on the seed, and the seeds are laterally connected by the growth of the island domain, forming one self-assembled layer.

The self-assembled layer is chemically bonded with the inorganic layer thereunder, which has an excellent interfacial bonding force and may be formed in a nanoscale thickness. Therefore, as shown in FIG. 7, a pinhole PH in the touch buffer layer (inorganic layer) 204 may be covered with a thin thickness, and as shown in FIG. 8, the seam on the side of the intermediate layer disconnection structure or the pinhole of at least one of the plurality of inorganic layers 181, 183, 204, and 205 may be covered.

The configuration DP, not described with reference to FIG. 8, refers to an intermediate layer dummy layer 162d and a second electrode dummy layer 163d, which are separated from the intermediate layer 162 and the second electrode 163 connected to the light emitting element of the subpixel SP, and which are generated as a result of the intermediate layer disconnection structure during an intermediate layer deposition process.

As shown in FIG. 8, each of the self-assembled layers SAL1 and SAL3 covers the seam region caused by the failure of the first and second inorganic encapsulation layers 181 and 183 being formed at a normal density under the protrusion pattern 148 after the formation of the first and second inorganic encapsulation layers 181 and 183 due to a steep step in the intermediate layer disconnection structure, whereby reliability against external air and moisture may be secured.

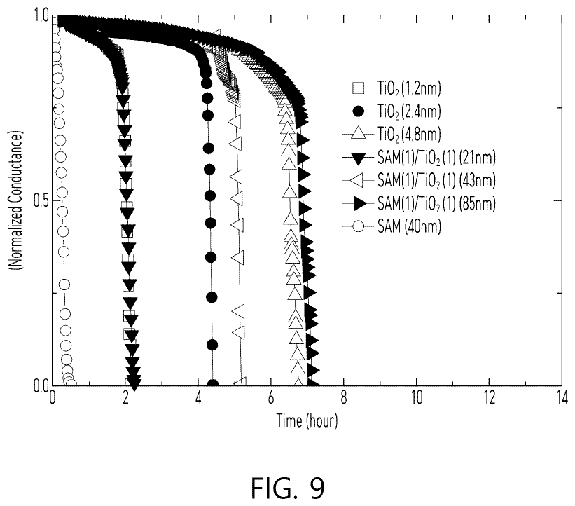

FIG. 9 is a graph showing conductivity of each self-assembled layer over time.

FIG. 9 shows that a calcium layer connected to an aluminum pattern was provided on a substrate, each layer was formed as a barrier layer, and the change in conductivity of the calcium layer in an environment of 60° C. and 85% moisture was measured.

It can be seen that the conductivity change is large when a self-assembled layer SAM is simply formed as a 40 nm barrier layer. On the other hand, it can be seen that a metal oxide layer, TiO₂, maintains the conductivity for a longer period of time than a single self-assembled layer SAM. Furthermore, it can be seen that the conductivity retention time of the metal oxide layer, TiO₂, increases as the thickness increases.

Meanwhile, when both the self-assembled layer SAM and the metal oxide layer are provided, the retention time of conductivity may be increased, compared to when only the metal oxide layer, TiO₂, is provided.

The experiment of FIG. 9 is significant in that it is confirmed that the resistance to high temperature and high humidity environments is improved when the self-assembled layer, which is an organic layer, is bonded with the metal oxide layer, which is an inorganic layer.

In the light emitting display device according to the embodiment of the present disclosure, a self-assembled layer of an organic layer component having a hydrophobic surface is provided for some or all of the plurality of inorganic layers located on the light emitting element, whereby it is possible to cover defects such as a pinhole or seam in each inorganic layer and to improve reliability against external air.

In the light emitting display device according to the embodiment of the present disclosure, the disconnection portion of the light emitting element is provided around the hole in the substrate corresponding to the sensor portion, whereby it is possible to prevent the inflow of external air or moisture through the hole in the substrate from affecting the subpixel.
A light emitting display device according to one embodiment of the present disclosure may comprise a substrate comprising an active area having a hole and a non-active area to surround the active area, a plurality of subpixels in the active area to be spaced apart from the hole by more than a first distance, a transistor at each of the plurality of subpixels, a light emitting element at each of the plurality of subpixels, the light emitting element comprising a first electrode connected to the transistor, a second electrode opposite the first electrode, and an intermediate layer between the first and second electrodes, an intermediate layer disconnection structure within the first distance, the intermediate layer disconnection structure surrounding the hole and having an undercut shaped section, an encapsulation layer disposed on the light emitting element, the encapsulation layer to cover at least the intermediate layer disconnection structure within the first distance; a touch sensor on the encapsulation layer: and a self-assembled layer on an upper surface of at least one of a plurality of inorganic layers included in the encapsulation layer and the touch sensor.

In a light emitting display device according to one embodiment of the present disclosure, the self-assembled layer may be an organic layer and bonded with the at least one of the plurality of inorganic layers.

In a light emitting display device according to one embodiment of the present disclosure, the self-assembled layer may have a thickness less than a thickness of the inorganic layer bonded therewith.

In a light emitting display device according to one embodiment of the present disclosure, the self-assembled layer may have a first surface corresponding to the at least one of the plurality of inorganic layers and a second surface opposite the first surface. The second surface of the self-assembled layer may be hydrophobic, and the second surface is located closer to an outside than the first surface.

In a light emitting display device according to one embodiment of the present disclosure, the self-assembled layer may comprise a head group, an alkyl chain, and a functional group. The head group may be bonded with the at least one of a plurality of inorganic layers.

In a light emitting display device according to one embodiment of the present disclosure, the alkyl chain of the self-assembled layer may have a bond length in a thickness direction from the upper surface of the at least one of a plurality of inorganic layers.

In a light emitting display device according to one embodiment of the present disclosure, the alkyl chain may have 2 to 30—CH₂— bonds.

In a light emitting display device according to one embodiment of the present disclosure, the head group of the self-assembled layer may comprise at least one of a —COOH group, a —SiH₃ group, a —SiCl₃ group, and a —SiF₃ group.

In a light emitting display device according to one embodiment of the present disclosure, the functional group of the self-assembled layer may be a —CH₃ group or a —CF₃ group.

In a light emitting display device according to one embodiment of the present disclosure, the self-assembled layer may have a thickness of 1 nm to 50 nm.

In a light emitting display device according to one embodiment of the present disclosure, the self-assembled layer may cover a seam on a side of the intermediate layer disconnection structure or at least one pinhole of the plurality of inorganic layers.

In a light emitting display device according to one embodiment of the present disclosure, the encapsulation layer may comprise a first inorganic encapsulation layer, an organic encapsulation layer, and a second inorganic encapsulation layer sequentially disposed on the light emitting element. The self-assembled layer may comprise at least one of a first self-assembled layer on an upper surface of the first inorganic encapsulation layer and a second self-assembled layer on an upper surface of the second inorganic encapsulation layer.

In a light emitting display device according to one embodiment of the present disclosure, the touch sensor may comprise a touch buffer layer on the encapsulation layer, a first touch metal line layer on the touch buffer layer, a touch intermediate insulating layer on the first touch metal line layer; and a second touch metal line layer on the touch intermediate insulating layer and an upper protective layer to cover the second touch metal line layer and the touch intermediate insulating layer. The self-assembled layer may comprise at least one of a third self-assembled layer on the touch buffer layer and a fourth self-assembled layer on the touch intermediate insulating layer.
In a light emitting display device according to one embodiment of the present disclosure, the encapsulation layer may comprise a first inorganic encapsulation layer, an organic encapsulation layer, and a second inorganic encapsulation layer sequentially disposed on the light emitting element. The touch sensor may comprise a touch buffer layer on the encapsulation layer, a first touch metal line layer on the touch buffer layer, a touch intermediate insulating layer on the first touch metal line layer, a second touch metal line layer on the touch intermediate insulating layer, and an upper protective layer to cover the second touch metal line layer and the touch intermediate insulating layer.
The self-assembled layer may comprise a first self-assembled layer on an upper surface of the first inorganic encapsulation layer, a second self-assembled layer on an upper surface of the second inorganic encapsulation layer, a third self-assembled layer on the touch buffer layer, and a fourth self-assembled layer on the touch intermediate insulating layer.
In a light emitting display device according to one embodiment of the present disclosure, any one of an infrared sensor, a camera, and an image sensor may be provided under the hole.

As is apparent from the above description, in a light emitting display device according to an embodiment of the present disclosure, a disconnection portion of an light emitting element is provided around a hole in a substrate corresponding to a sensor portion, whereby it is possible to prevent the inflow of external air or moisture through the hole in the substrate from affecting a subpixel.

In the light emitting display device according to the embodiment of the present disclosure, a self-assembled layer is provided on an upper surface of at least some of a plurality of inorganic layers provided on the light emitting element such that the self-assembled layer covers a pinhole in the inorganic layer or a seam occurring around the disconnection portion of the light emitting element, thereby preventing deterioration due to external moisture permeation and securing reliability of the display device.

In the light emitting display device according to the embodiment of the present disclosure, the self-assembled layer includes an alkyl chain, a head group located on one side of the alkyl chain so as to correspond to the upper surface of the inorganic layer, and a functional group located on the other side of the alkyl chain, wherein the functional group is hydrophobic, thereby making it advantageous to realize hydrophobicity of the self-assembled layer and thus making the self-assembled layer resistant to external air, such as moisture.

In the light emitting display device according to the embodiment of the present disclosure, the self-assembled layer, which has a nanoscale thickness, covers seams or residual pinholes in the inorganic layer, whereby it is possible to secure reliability even without increasing the thickness of the display device so as not to impair luminous efficacy or permeability in display characteristics.

In the light emitting display device according to the embodiment of the present disclosure, it is possible to reduce the defect rate by preventing deterioration of device reliability and to achieve ESG (environmental/social/governance) goals by reducing production energy through process optimization.

In addition to the above effects, the specific effects of the present disclosure have been described in the detailed description of the disclosure above.

What is claimed is:

1. A light emitting display device comprising:
a substrate comprising an active area comprising a hole and a non-active area configured to surround the active area;
a plurality of subpixels in the active area configured to be spaced apart from the hole by more than a first distance;
a transistor at each of the plurality of subpixels;
a light emitting element at each of the plurality of subpixels, the light emitting element comprising a first electrode connected to the transistor, a second electrode opposite the first electrode, and an intermediate layer between the first and second electrodes;
an intermediate layer disconnection structure within the first distance, the intermediate layer disconnection structure surrounding the hole and comprising an undercut shaped section;
an encapsulation layer disposed on the light emitting element, the encapsulation layer to cover at least the intermediate layer disconnection structure within the first distance;
a touch sensor disposed on the encapsulation layer; and
a self-assembled layer disposed on an upper surface of at least one of a plurality of inorganic layers included in the encapsulation layer and the touch sensor.

2. The light emitting display device according to claim 1, wherein the self-assembled layer is an organic layer bonded with the at least one of the plurality of inorganic layers.

3. The light emitting display device according to claim 2, wherein the self-assembled layer has a thickness smaller than a thickness of the inorganic layer bonded therewith.

4. The light emitting display device according to claim 1, wherein:
the self-assembled layer has a first surface corresponding to the at least one of the plurality of inorganic layers and a second surface opposite the first surface, and
the second surface of the self-assembled layer is hydrophobic, wherein the second surface is located closer to an outside than the first surface.

5. The light emitting display device according to claim 1, wherein:
the self-assembled layer comprises a head group, an alkyl chain, and a functional group, and
the head group is bonded with the at least one of a plurality of inorganic layers.

6. The light emitting display device according to claim 5, wherein the alkyl chain of the self-assembled layer has a bond length in a thickness direction from the upper surface of the at least one of a plurality of inorganic layers.

7. The light emitting display device according to claim 5, wherein the alkyl chain comprises from 2 to 30—CH₂— bonds.

8. The light emitting display device according to claim 5, wherein the head group of the self-assembled layer comprises at least one of a —COOH group, a —SiH₃ group, a —SiCl₃ group, and a —SiF₃ group.

9. The light emitting display device according to claim 5, wherein the functional group of the self-assembled layer is a —CH₃ group or a —CF₃ group.

10. The light emitting display device according to claim 1, wherein the self-assembled layer has a thickness of 1 nm to 50 nm.

11. The light emitting display device according to claim 1, wherein:
the self-assembled layer covers a seam on a side of the intermediate layer disconnection structure or at least one pinhole of the plurality of inorganic layers.

12. The light emitting display device according to claim 1, wherein:
the encapsulation layer comprises a first inorganic encapsulation layer, an organic encapsulation layer, and a second inorganic encapsulation layer sequentially disposed on the light emitting element, and
the self-assembled layer comprises at least one of a first self-assembled layer on an upper surface of the first inorganic encapsulation layer and a second self-assembled layer on an upper surface of the second inorganic encapsulation layer.

13. The light emitting display device according to claim 1, wherein the touch sensor comprises:
a touch buffer layer on the encapsulation layer;
a first touch metal line layer on the touch buffer layer;
a touch intermediate insulating layer on the first touch metal line layer;
a second touch metal line layer on the touch intermediate insulating layer; and
an upper protective layer to cover the second touch metal line layer and the touch intermediate insulating layer,
wherein the self-assembled layer comprises at least one of a third self-assembled layer on the touch buffer layer and a fourth self-assembled layer on the touch intermediate insulating layer.

14. The light emitting display device according to claim 1, wherein:
the encapsulation layer comprises a first inorganic encapsulation layer, an organic encapsulation layer, and a second inorganic encapsulation layer sequentially disposed on the light emitting element,
the touch sensor comprises a touch buffer layer on the encapsulation layer, a first touch metal line layer on the touch buffer layer, a touch intermediate insulating layer on the first touch metal line layer, a second touch metal line layer on the touch intermediate insulating layer, and an upper protective layer to cover the second touch metal line layer and the touch intermediate insulating layer, and
the self-assembled layer comprises a first self-assembled layer on an upper surface of the first inorganic encapsulation layer, a second self-assembled layer on an upper surface of the second inorganic encapsulation layer, a third self-assembled layer on the touch buffer layer, and a fourth self-assembled layer on the touch intermediate insulating layer.

15. The light emitting display device according to claim 1, wherein at least one of an infrared sensor, a camera, and an image sensor is provided under the hole.
